(19) United States
(12) Patent Application Publication
(10) Pub. No.: US 2022/0263266 A1
(43) Pub. Date: Aug. 18, 2022

(54) ELECTRIC CONNECTOR AND MOVABLE PLATFORM

(71) Applicant: SZ DJI TECHNOLOGY CO., LTD., Shenzhen (CN)

(72) Inventors: Ruiqiang ZHANG, Shenzhen (CN); Rizhao LI, Shenzhen (CN); Yanxin HUANG, Shenzhen (CN)

(73) Assignee: SZ DJI TECHNOLOGY CO., LTD., Shenzhen (CN)

(21) Appl. No.: 17/736,033

(22) Filed: May 3, 2022

Related U.S. Application Data
(63) Continuation of application No. PCT/CN2019/115831, filed on Nov. 5, 2019.

(51) Int. Cl. H01R 13/52; H05K 5/00; H05K 5/06; B64C 39/02

(52) U.S. Cl. CPC H01R 13/5202; H05K 5/0069; H01R 12/7088; B64C 39/02; H05K 5/069

(57) ABSTRACT

An electric connector and a movable platform are provided. The electric connector includes a housing, a circuit board, and an electric connection part. The circuit board is arranged in the housing to connect to a load of the movable platform. The electric connection part is displaceable relative to the housing, and at least one portion of the electric connection part may extend out of the housing. A sealing ring may be provided in an outer peripheral surface of the electric connection part that extends outside the housing to seal the gap between the electric connection part and the casing of the movable platform, so as to isolate the circuit board of the housing. The electric connection part may be electrically connected to the circuit board and an external battery respectively to enable the circuit board to process electrical signals output from the battery.

### RELATED APPLICATIONS

The present patent document is a continuation of PCT Application Serial No. PCT/CN2019/115831, filed on Nov. 5, 2019, designating the United States and published in English, which is hereby incorporated by reference.

### TECHNICAL FIELD

The present disclosure relates to the field of electric connector technologies, and specifically, to an electric connector and a movable platform.

### BACKGROUND

In related technologies, an unmanned aerial vehicle may include a battery, and the unmanned aerial vehicle may produce a large vibration(s) during its flight. Thus, for a long period under a vibration condition, metal terminals of the battery may wear out; resulting in higher contact impedance at two ends of a connection structure, and the temperature at the connection structure may be quite high. In a serious situation, this may burn the battery or a circuit(s) of the unmanned aerial vehicle.

### BRIEF SUMMARY

The present disclosure provides an electric connector and a movable platform.

An electric connector is provided in some exemplary embodiments of the present disclosure, including: a housing; a circuit board, fixedly mounted in the housing; an electric connection part; and a sealing ring on an outer peripheral surface of the at least one portion of the electric connection part that extends out of the housing, where at least one portion of the electric connection part extends out of the housing, the electric connection part and the housing are in a displaceable connection to allow the electric connection part to be displaceable relative to the housing and the circuit board, the electric connection part is configured to electrically connect to an external battery and the circuit board respectively to enable the circuit board to process an electrical signal output from the battery, the outer peripheral surface of the at least one portion of the electric connection part that extends out of the housing includes a first recess and a second recess spaced apart from the first recess, the sealing ring is located in the first recess, and upon mounting the electric connector on a movable platform, a rubber ring is sleeved over the second recess, and the sealing ring seals a gap between the electric connection part and a housing of a movable platform to isolate the circuit board in the housing.

An electric connector is provided in some exemplary embodiments of the resent disclosure, including: a housing; an electric connection part; at least one connecting plate including at least one a mounting hole; at least one mounting post; and an elastic body disposed between the at least one mounting post and a hole wall of the at least one mounting hole, where at least one portion of the electric connection part extends out of the housing, the electric connection part and the housing are in a displaceable connection via the elastic body to allow the electric connection part to displace relative to the housing, the electric connection part is configured to connect to an external battery and an external circuit board respectively to enable the circuit board to process an electrical signal output from the battery, the electric connection part is fixedly connected to the at least one connecting plate, the at least one mounting post passes through the at least one mounting hole, and the elastic body allows the electric connection part to displace relative to the housing.

A movable platform is provided in some exemplary embodiments of the resent disclosure, including: a casing, including a casing opening; and an electric connector in the casing and extending from the casing through the casing opening, including: a housing, a circuit board, fixedly mounted in the housing, an electric connection part, and a sealing ring on an outer peripheral surface of the at least one portion of the electric connection part that extends out of the housing, where at least one portion of the electric connection part extends out of the housing, the electric connection part and the housing are in a displaceable connection to allow the electric connection part to be displaceable relative to the housing and the circuit board, the electric connection part is configured to electrically connect to an external battery and the circuit board respectively to enable the circuit board to process an electrical signal output from the battery, the outer peripheral surface of the at least one portion of the electric connection part that extends out of the housing includes a first recess and a second recess spaced apart from the first recess, the sealing ring is located in the first recess, and upon mounting the electric connector on a movable platform, a rubber ring is sleeved over the second recess, and the sealing ring seals a gap between the electric connection part and a housing of a movable platform to isolate the circuit board in the housing.

Certain additional aspects and advantages of the present disclosure may be provided in the following description; others would become apparent in light of the following description, or may be learned by practicing the present disclosure.

### BRIEF DESCRIPTION OF THE DRAWINGS

To make it easy to understand the aspects and advantages of the embodiments of the present disclosure, the following briefly describes the accompanying drawings for describing some exemplary embodiments, in which:

FIG. 1 is schematic diagram of the structure of a movable platform according to some exemplary embodiments of the present disclosure;

FIG. 2 is a schematic diagram of part of the structure a movable platform according to some exemplary embodiments of the present disclosure;

FIG. 3 is an enlarged schematic diagram of 11 in FIG. 2;

FIG. 4 is a schematic diagram of the three-dimensional structure of an electric connector according to some exemplary embodiments of the present disclosure;

FIG. 5 is a cross-sectional schematic diagram of an electric connector according to some exemplary embodiments of the present disclosure;

FIG. 6 is a schematic perspective exploded diagram of an electric connector according to some exemplary embodiments of the present disclosure;

FIG. 7 is a schematic diagram of part of the structure of an electric connector according to some exemplary embodiments of the present disclosure;

FIG. 8 is a schematic diagram of part of the structure of an electric connector according to some exemplary embodiments of the present disclosure;

FIG. 9 is a schematic diagram of part of the structure of an electric connector according to some exemplary embodiments of the present disclosure;

FIG. 10 is a schematic diagram of part of the structure of an electric connector according to some exemplary embodiments of the present disclosure;

FIG. 11 is a schematic diagram of part of the structure of an electric connector according to some exemplary embodiments of the present disclosure;

FIG. 12 is a schematic diagram of part of the structure of an electric connector according to some exemplary embodiments of the present disclosure;

FIG. 13 is a schematic diagram of part of the structure of an electric connector according to some exemplary embodiments of the present disclosure;

FIG. 14 is a schematic diagram of the structure of an elastic body of an electric connector according to some exemplary embodiments of the present disclosure;

FIG. 15 is a schematic diagram of the structure of a guide member of an electric connector according to some exemplary embodiments of the present disclosure;

FIG. 16 is a schematic diagram of part of the structure of an electric connector according to some exemplary embodiments of the present disclosure;

FIG. 17 is a schematic diagram of part of the structure of an electric connector according to some exemplary embodiments of the present disclosure;

FIG. 18 is a schematic diagram of part of the structure of an electric connector according to some exemplary embodiments of the present disclosure;

FIG. 19 is a schematic diagram of part of the structure of an electric connector according to some exemplary embodiments of the present disclosure; and

FIG. 20 is a schematic diagram of part of the structure of an electric connector according to some exemplary embodiments of the present disclosure.

### DESCRIPTION OF THE REFERENCE NUMERALS

movable platform 1000;

electric connector 100, housing 10, first through hole 12, mounting post 14, first post 142, first notch 1422, second post 144, fourth recess 146, first housing 16, second housing 18, third through hole 11, circuit board 20, mounting hole 22, bounding pad 24, electric connection part 30, covering member 32, first recess 322, second recess 324, third recess 326, flange 328, electric connection member 34, mounting part 342, conductive member 344, sealing ring 40, elastic body 50, second through hole 52, fifth recess 522, first projection 524, sixth recess 54, seventh recess 542, second projection 544, power distribution wire 60, guide member 70, guide hole 72, second notch 722, clamping part 74, connecting plate 80, flexible wire 90;

casing 200, casing opening 220, eave 240.

### DETAILED DESCRIPTION

Embodiments of the present disclosure will be described in detail below, and some exemplary embodiments are shown in the accompanying drawings. The same or similar symbols denote the same or similar components or components having the same or similar functions.

The embodiments described below by reference to the accompanying drawings are exemplary and are intended to explain the present disclosure only and are not a limitation to the present disclosure.

In the description of the present disclosure, it is to be understood that the terms “center”, “longitudinal”, “transverse”, “length”, “width”, “thickness”, “up”, “down”, “front”, “back”, “left”, “right”, “vertical”, “horizontal”, “top”, “bottom”, “inside”, “inside”, “outside”, “clockwise”, “counterclockwise” and the like indicate orientation or positional relationships based on the orientation or positional relationships shown in the accompanying drawings, and are intended only to facilitate and simplify the description of the present disclosure, which are not intended to indicate or imply that the device or element referred to must have a particular orientation, or must be constructed or operated in a particular orientation. Therefore, they do not limit the present disclosure. In addition, the terms “first” and “second” are used for descriptive purposes only and are not to be understood as indicating or implying relative importance or implicitly specifying the number of technical features indicated. Therefore, the features defined as “first” and “second” may explicitly or implicitly include one or more of the features. For the purposes of the description of the present disclosure, “plurality” means two or more, unless otherwise explicitly and specifically limited.

In the description of the present disclosure, it should be noted that, unless otherwise explicitly specified and defined, the terms “assembly”, “connected”, “connection” should be understood in a broad sense, for example, they may be a fixed connection, a removable connection, or an integral connection. It may be a mechanical connection or an electrical connection. It may be a direct connection or an indirect connection through an intermediate medium, a communication between two components or an interactive relationship between two components. To a person of ordinary skill in the art, the specific meaning of the above terms in this disclosure may be understood based on the contexts thereof.

In the present disclosure, unless otherwise explicitly specified and defined, a first feature being “above” or “below” a second feature may include direct contact between the first and second features, or it may include an indirect contact between the first and second features via a separate feature between them. Furthermore, a first feature being “above” and “on top of” a second feature may include the first feature being directly above and diagonally above the second feature, or simply indicating that the first feature is horizontally higher above the second feature. A first feature being “below”, “at bottom of” and “under” a second feature may include the first feature being directly below and diagonally below the second feature, or simply indicating that the first feature is lower than the horizontal height of the second feature.

The disclosure herein provides a plurality of exemplary embodiments or examples for implementing the different structures of the present disclosure. In order to simplify the disclosure of the present disclosure, the components and settings in some examples will be described herein. They are, of course, examples only and are not intended to limit the present disclosure. In addition, the present disclosure may repeat reference numerals and/or reference letters in different examples; such repetition is for the purpose of simplicity and is not in itself indicative of a relationship between the various embodiments and/or settings discussed. In addition, various examples of specific processes and materials are provided in the present disclosure, but a person of ordinary skill in the art may be aware of other applications of processes and/or the use of other materials.

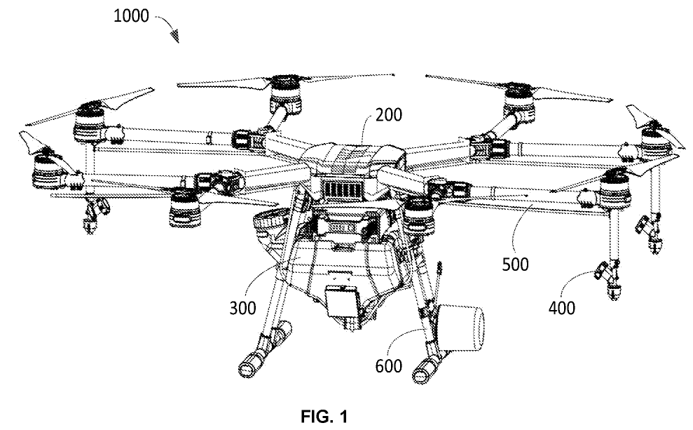

Referring to FIG. 1, an electric connector 100 may be applied to a movable platform 1000 in the present disclosure. Specifically, the movable platform 1000 may include, but is not limited to, an unmanned aerial vehicle (for example, an agricultural unmanned aerial vehicle), an aerial apparatus or aerial device, a robot, a movable cart, etc. The electric connector 100 may be connected to a battery of the movable platform 1000 to transmit electronic power to the movable platform 1000, so as to enable the movable platform 1000 to operate.

The movable platform 1000 in some exemplary embodiments of the present disclosure may include a casing 200, an electric connector 100, and a battery (not shown in the figure). The electric connector 100 and the battery are both arranged in the casing 200, the battery may have a battery connection terminal, the electric connector 100 may be electrically connected to the battery connection terminal to enable the battery to transmit power or signals to the movable platform 1000. Specifically, referring to FIG. 1, taking the movable platform 1000 being an agricultural unmanned aerial vehicle as an example, the agricultural unmanned aerial vehicle may also include a liquid storage tank 300 for storing a liquid, a spray assembly 400, an arm 500, a diaphragm pump (not shown in the figure), and other structures. The liquid storage tank 300 may be used to spray, and may be fixed on a landing device 600 of the agricultural unmanned aerial vehicle by fixing members such as screws. The mounting method of the spray assembly 400 on the agricultural unmanned aerial vehicle 1000 is not specifically limited, for example, it may be fixed on the casing 200 by a snap connection, a screw connection, or other fixing connections. In the example shown in FIG. 1, the spray assembly 400 may be arranged on a side of the arm 500 away from the electric connector 100. The spray assembly 400 may include a spray head (not shown in the figure). The spray assembly 400 may spray a liquid through the spray head for irrigation. The diaphragm pump may communicate with the liquid storage tank 300 and the spray assembly 400 through a pipe(s). The diaphragm pump may be used to pump the liquid from the liquid storage tank 300 to the spray assembly 400 for spray. The battery may be connected to the power system of the agricultural unmanned aerial vehicle via the electric connector 100, such as a propeller, a diaphragm pump, etc., so that the agricultural unmanned aerial vehicle may fly and spray the liquid for irrigation.

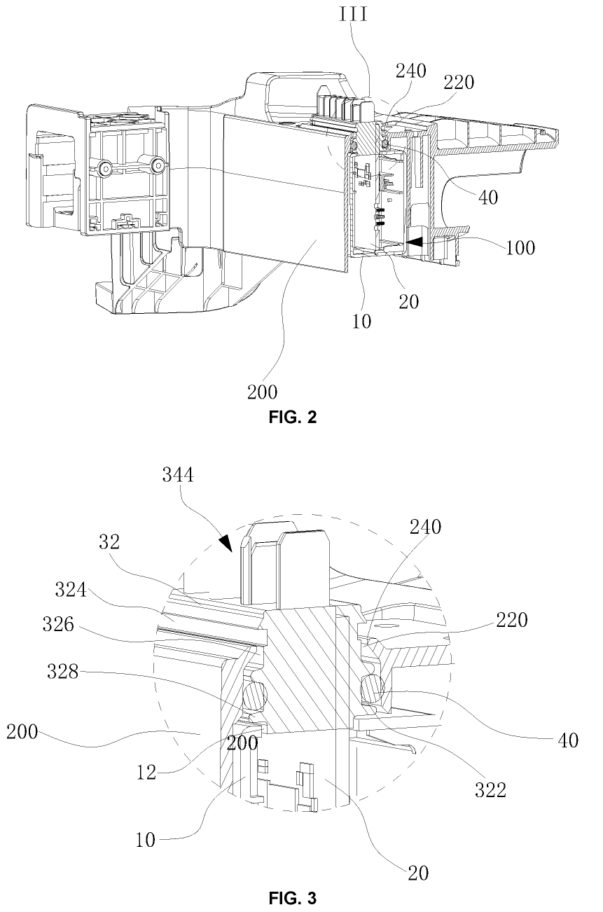

Referring FIG. 2 and FIG. 3, in some exemplary embodiments, the casing 200 may be provided with a casing opening 220, the periphery of the casing opening 220 may be provided with an eave 240 inclined upward toward a central axis of the through hole, and the electric connector 100 may be mounted in an upward direction from the inside of the casing 200, so that the electric connector 100 may partly extend from the through hole to the outside of the casing 200, thus the electric connector 100 may be connected to the battery connector. The eave 240 may be used to catch the electric connector 100 to prevent the electric connector 100 from coming out of the casing 200 when the casing 200 vibrates.

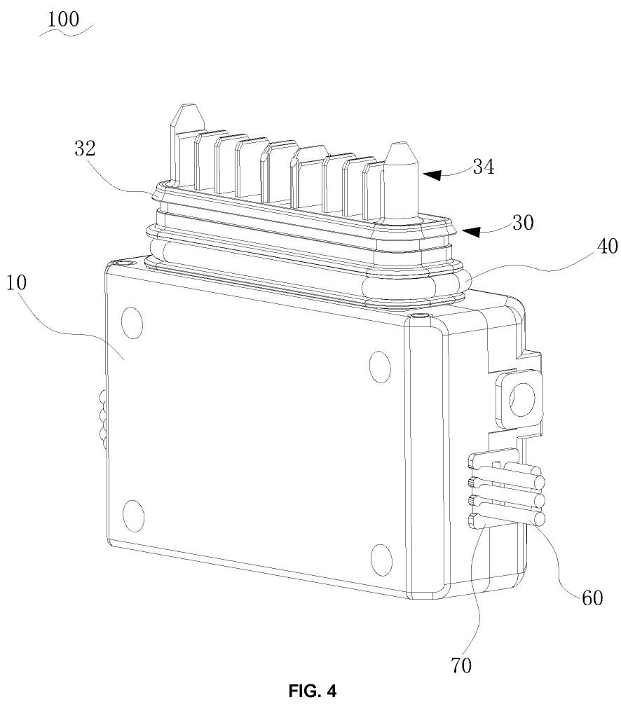

The following describes an electric connector 100 in details in some exemplary embodiments of the present disclosure. Referring to FIG. 4, the electric connector 100 may include a housing 10, a circuit board 20, an electric connection part 30, a sealing ring 40, an elastic body 50, a power distribution wire(s) 60, and two guide members 70. The circuit board 20, the electric connection part 30, the sealing ring 40, the elastic body 50, the power distribution wire 60 and the guide members 70 may be assembled in the housing 10.

Referring FIG. 4 to FIG. 6, in some exemplary embodiments, the housing 10 may be made of plastic and other materials, the upper surface of the housing 10 may be provided with a first through hole 12, and a side plate of the housing 10 may be provided with third through holes 11, the first through hole 12 may be used to allow the electric connection part 30 to extend, the number of the third through holes 11 may be two, the two third through holes 11 are respectively provided on opposite side plates of the housing 10, each of the third through holes 11 is used to mount one guide member 70. In addition, a mounting post 14 may be provided in the housing 10, and the mounting post 14 is used to mount the elastic body 50.

Specifically, in some exemplary embodiments shown in the figures, the housing 10 may include a first housing 16 and a second housing 18, the first housing 16 and the second housing 18 are detachably connected, which facilitates mounting the components in the housing 10, such as the circuit board 20, the electric connection part 30, etc. The first housing 16 and the second housing 18 may be connected in a snap connection, a screw connection, or the like. The upper surface of the first housing 16 is provided with a notch, and the upper surface of the second housing 18 is also provided with a notch, the first through hole 12 is formed by connecting the notch on the upper surface of the first housing 16 with the notch on the upper surface of the second housing 18. In addition, a side plate of the first housing 16 is also provided with two notches, a side plate of the second housing 18 is also provided with two notches, the two third through holes 11 are formed by connecting the notches of the side plate of the first housing 16 with the notches of the side plate of the second housing 18, the side plate of the housing 10 is formed by connecting the side plate of the first housing 16 and the side plate of the second housing 18. It should be understood that in some exemplary embodiments, the housing 10 may be made of other materials not limited to plastic; the connection method of the first housing 16 and the second housing 18 is not limited herein.

Further, in some exemplary embodiments, the shape of the mounting post 14 is cylindrical, and the outer peripheral surface of the mounting post 14 is provided with a fourth recess 146. The fourth recess 146 may be ring-shaped, and the fourth recess 146 is used for mounting the elastic body 50.

Specifically, the mounting post 14 may include a first post 142 and a second post 144. The first post 142 is set in the first housing 16, the second post 144 is disposed inside the second housing 18, the mounting post 14 is formed by connecting the first post 142 and the second post 144. A first notch 1422 is provided on the outer peripheral surface of one end of the first post 142 close to the second post 144, and the first notch 1422 may be used to mount the elastic body 50. When the elastic body 50 is being mounted, the first housing 16 and the second housing 18 may not be connected together first, while the elastic body 50 may be sleeved over the first notch 1422 of the first post 142. Since the part of the first post 142 having the first notch 1422 is smaller in size than the rest of the first post 142, the elastic body 50 may fit easily out of the first post 142. After the elastic body 50 is mounted on the first post 142, the first housing 16 and the second housing 18 may be connected together, the first post 142 may be connected to the second post 144 correspondingly to form the mounting post 14, the elastic body 50 may be arranged at the first notch 1422, and the end face of the second post 144 may surround the outer side of the first notch 1422 to form the fourth recess 146.

It should be understood that, in some exemplary embodiments, the shape of the mounting post 14 is not limited to a cylindrical shape, and may also be other regular or irregular polygonal post, as long as that the elastic body can be securely mounted thereon. This is noted limited herein. In addition, in some exemplary embodiments, the fourth recess 146 may be formed by recessing from the outer periphery of the mounting post 14 toward the interior of the mounting post 14. It should be understood that, in some exemplary embodiments, the fourth recess 146 may also be arranged on a baffle convexly provided on the outer periphery of the mounting post 14. This is noted limited herein. In addition, in some exemplary embodiments shown in the figures, the elastic body 50 may be arranged at the first notch 1422 of the second post 144, and then the first post 142 is connected to the second post 144 to surround the first notch 1422 so as to form the fourth recess 146. It should be understood that, in some exemplary embodiments, the mounting post 14 may also be cylindrical; the middle portion of the mounting post 14 may recess toward the interior of the mounting post 14 to form the fourth recess 146. Thus, when the elastic body 50 is mounted, it can be sleeved over the mounting post 14 from one end thereof, and eventually arranged within the fourth recess 146.

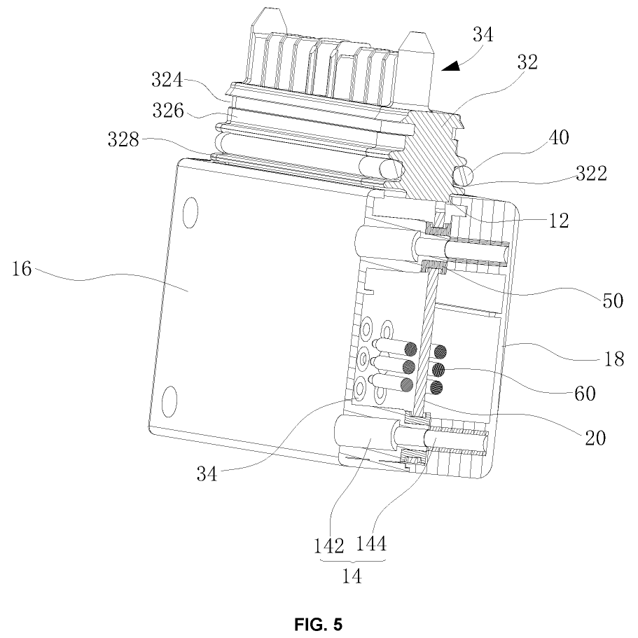

Referring to FIG. 5 to FIG. 7, in some exemplary embodiments, the circuit board 20 may be arranged inside the housing 10. The circuit board 20 may be fixedly connected to the electric connection part 30 and may be in a displaceable connection with the housing 10. That is, the circuit board 20 may be displaceably connected to the housing 10, so that there is a certain relative movable distance (that is, a distance that allows for relative movement therebetween) between the circuit board 20 and the housing 10. In addition, the circuit board 20 may be used to connect a load of the movable platform 1000. Taking the movable platform 1000 being an agricultural unmanned aerial vehicle as an example, the load may include a propeller assembly to drive the agricultural unmanned aerial vehicle in flight and a power system such as a diaphragm pump. Specifically, the circuit board 20 may be provided with a bounding pad 24. The bounding pad 24 is used to connect the power distribution wire 60, so that the circuit board 20 may be connected to the load of the movable platform 1000.

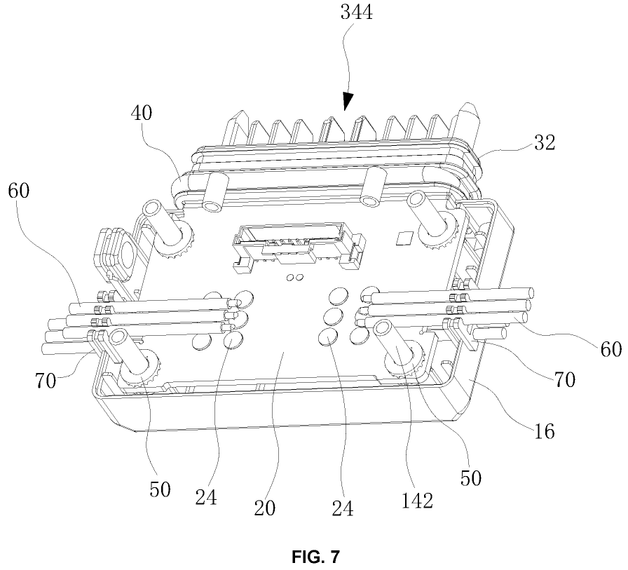

Further, referring to FIG. 7 to FIG. 9, the circuit board 20 may be provided with a mounting hole 22, the mounting post 14 of the housing 10 may penetrate the mounting hole 22, and the mounting hole 22 may correspond to the fourth recess 146 on the mounting post 14. In some exemplary embodiments shown in the figures, corresponding to the mounting post 14, the shape of the mounting hole 22 may also be cylindrical. It should be understood that the shapes of the mounting post 14 and the mounting hole 22 are not limited to a cylindrical shape, and may also be other regular or irregular polygonal shapes. This not limited herein.

Referring to FIG. 5, the electric connection part 30 may be electrically connected to the circuit board 20 and an external battery respectively, to allow the circuit board 20 to process electrical signals output from the battery. Specifically, the electric connection part 30 may be fixedly connected to the circuit board 20, and at least one portion of the electric connection part 30 may extend out of the housing 10 through the first through hole 12. That is, in some exemplary embodiments, the electric connection part 30 may be fixedly connected to the circuit board 20, and the circuit board 20 may be displaceably connected to the housing 10. Therefore, when the battery is mounted on the movable platform 1000, the battery connection terminal of the battery and the electric connection part 30 of the electric connector 100 are securely connected to each other for the transmission of the battery electrical signal. During the movement, the movable platform 1000 may cause vibrations, and the movable platform 1000 may transfer the vibrations to the housing 10 and the circuit board 20 via the casing 200, thereby causing the housing 10 and the circuit board 20 to vibrate together. In some exemplary embodiments, the electric connection part 30 may be connected to the housing 10 in a displaceable connection, so that there is a certain relative movable distance between the electric connection part 30 and the housing 10. During the vibration of the housing 10, the electric connection part 30 of the electric connector 100 does not vibrate or has a smaller vibration due to the distance, so as to ensure that there is no relative movement or less relative movement between the electric connector 100 and the battery, and avoid wearing of the electric connection part 30 and the battery. Similarly, when there is a vibration, the battery may drive the electric connection part 30 of the electric connector 100 to displace, thus the electric connection part 30 may displace relative to the housing 10 and the circuit board 20, the housing 10 and the circuit board 20 do not vibrate or have a less vibration, thereby avoiding tearing between the electric connection part 30 and the battery connection terminal.

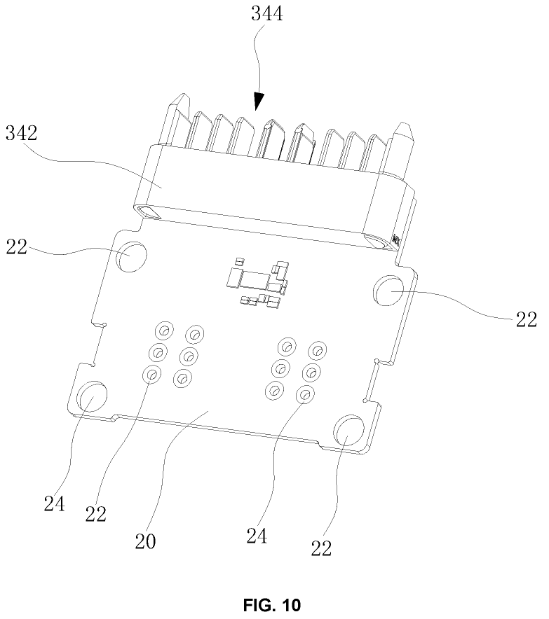

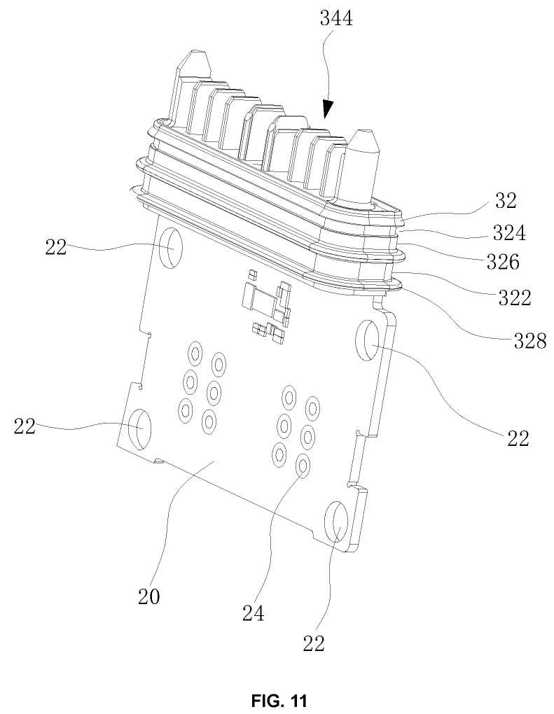

Referring to FIG. 7 to FIG. 11, in some exemplary embodiments, the electric connection part 30 may include a covering member 32 and an electric connection member 34, the covering member 32 and the electric connection member 34 are both extended out of the housing 10. The covering member 32 may cover the electric connection member 34, the electric connection member 34 may be electrically connected to the circuit board 20 and may protrude from the covering member 32. Therefore, the covering member 32 may protect the electric connection member 34, to avoid the relative movement between the electric connection member 34 and the housing 10 which may cause wearing of the electric connection member 34. In some exemplary embodiments, the covering member 32 may have a friction with the casing 200 of the movable platform 1000 when the electric connection part 30 displaces relative to the housing 10. Therefore, the electric connection member 34 may be protected from wearing.

Specifically, the electric connection part 30 may extend from the first through hole 12 of the housing 10 to the exterior of the housing 10, and a gap may exist between the electric connection part 30 and the hole wall of the first through hole 12 to facilitate the movement of the electric connection part 30. In some cases, the electric connection part 30 may touch the hole wall of the first through hole 12 and have friction with the hole wall of the first through hole 12 during the movement of the electric connection part 30. Since the electric connection member 34 is the part for the electric connection, to avoid the electric connection member 34 from a friction against the hole wall of the first through hole 12 during the movement of the electric connection part 30, the electric connection member 34 may be covered by the covering member 32. Thus, instead of the friction between the electric connection part 30 and the hole wall of the first through hole 12, it is the friction between covering member 32 and the hole wall of the first through hole 12 that actually occurs, thereby avoiding the wearing of the electric connection member 34.

Further, referring to FIG. 3, and FIG. 5 to FIG. 8, in some exemplary embodiments, the outer peripheral surface of the covering member 32 may be provided a first recess 322, a second recess 324, a third recess 326 and a flange 328. The first recess 322 may be used to mount a sealing ring 40. The second recess 324 may be spaced apart from the first recess 322, and the second recess 324 may be sleeved by a rubber ring (not shown in the figures) when the electric connector 100 is being mounted on the movable platform 1000. The third recess 326 may be used to cooperate with the eave 240 of the casing 200 to limit the displacement of the electric connection part 30.

Specifically, the first recess 322 may be annularly arranged on the outer peripheral surface of the covering member 32, the outer peripheral surface of the covering member 32 may be in the shape of a runway. When the electric connector 100 is mounted on the movable platform 1000, the first recess 322 may be arranged inside the casing 200, and the sealing ring 40 may seal the gap between the electric connection part 30 and the casing 200 to isolate the circuit board 20 in the housing 10. In some exemplary embodiments, the first recess 322 may be formed by recessing the outer periphery of the electric connection part 30 toward the interior of the electric connection part 30. It should be understood that, in some exemplary embodiments, the first recess 322 may also be disposed on a baffle convexly provided on the outer periphery of the covering member 32, and the specific arrangement is not specifically limited herein.

The second recess 324 may be in the shape of a runway shape. When the electric connector 100 is mounted on the movable platform 1000, the second recess 324 may be arranged outside the casing 200, a rubber ring may be arranged at the second recess 324, and the rubber ring may be used to cover the gap between the electric connection part 30 and the hole wall of the first through hole 12.

The third recess 326 may be located between the first recess 322 and the second recess 324, and in communication with the second recess 324, the depth of the third recess 326 is different from the depth of the second recess 324, and the eave 240 of the casing 200 is snapped into the third recess 326.

Specifically, in some exemplary embodiments, the electric connector 100 may be mounted in a direction from the interior of the casing 200 toward the through hole, so that the electric connection part 30 may extend from the first through hole 12 to the outside, and the eave 240 may be snapped into the third recess 326 and located below the rubber ring sleeved over the second recess 324. Generally, the housing 10 may be fixed in the casing 200. When the casing 200 vibrates, it may drive the housing 10 to vibrate. Due to the arrangement that the electric connection part 30 is displaceably connected to the housing 10, when the housing 10 vibrates, one of the possible movement directions of the electric connection part 30 is upward. Since the eave 240 is snapped into the third recess 326, the inner wall of the third recess 326 may be blocked by the eave 240 during the upward movement of the electric connection part 30, making it impossible for the electric connection part 30 to move up further, thereby avoiding excessive upward movement of the electric connection part 30. In addition, as may be seen above, the eave 240 of the casing 200 may be snapped into the third recess 326, and during the displacement of the electric connection part 30, the friction between the eave 240 of the casing 200 and the electric connection part 30 is actually the friction between the covering member 32 and the eave 240, thereby avoiding wearing of the electric connection member 34 and extending the service life of the electric connector 100.

In addition, in some exemplary embodiments shown in the Figures, the depth of the second recess 324 may be greater than the depth of the third recess 326. It should be understood that, in some exemplary embodiments, the depth of the second recess 324 may be the same as the depth of the third recess 326, or may be smaller than that of the third recess 326, which is not limited herein.

Further, referring to FIG. 3, and FIG. 5 to FIG. 8, in some exemplary embodiments, a flange 328 may be provided on the outer peripheral surface of the covering member 32, and the flange 328 extends out of the first recess 322 first. The flange 328 may cover the gap between the electric connection part 30 and the hole wall of the first through hole 12 of the housing 10. Therefore, even in the event that water accidentally enters the casing 200 of the movable platform 1000, the flange 328 may shield the water and further isolate the circuit board 20 in the housing 10.

Specifically, in the orientation shown in FIG. 3, the flange 328 may be arranged under the first recess 322, that is, the flange 328 may be arranged under the sealing ring 40 in the first recess 322 and close to the housing 10. If water leaks downward through the sealing ring 40, it will be blocked by the flange 328 from entering the gap between the electric connection part 30 and the hole wall of the first through hole 12, thereby further isolating the circuit board 20 in the housing 10.

In addition, in some exemplary embodiments, the covering member 32 may be made of a material with high wear resistance and strength. For example, the covering member 32 may be made of polyamide. Therefore, during the displacement of the electric connection part 30, the covering member 32 may have a friction with the eave 240. The covering member 32 may be made of a material with high wear resistance and strength, which may extend the service life of the covering member 32

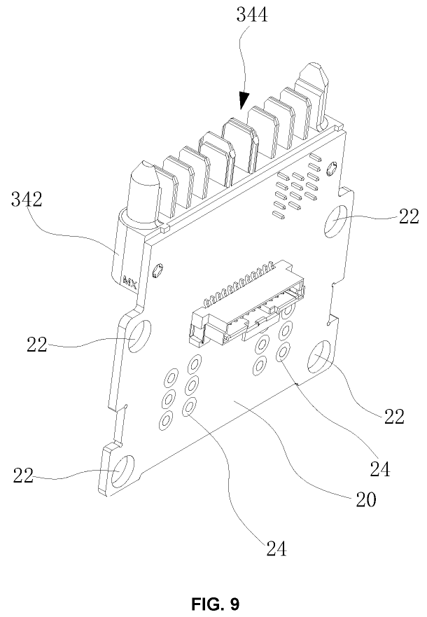

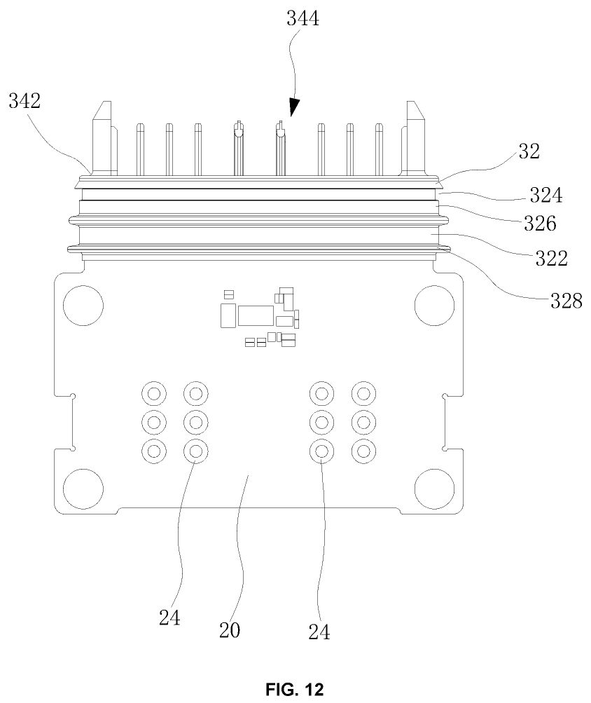

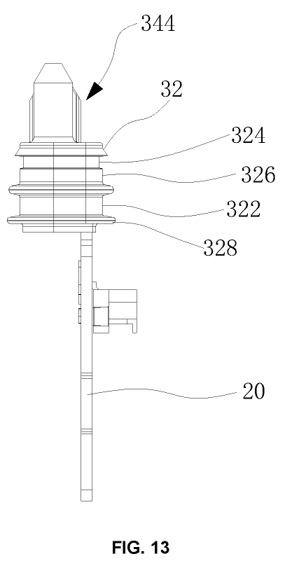

Referring to FIG. 9 to FIG. 13, in some exemplary embodiments, the electric connection member 34 may protrude from the covering member 32. The electric connection member 34 may include a mounting part 342 and a plurality of conductive members 344, a portion of the plurality of conductive members 344 may be arranged in the mounting part 342, the mounting part 342 is covered by the plurality of covering members 32, and the plurality of conductive members 344 may protrude from the covering member 32. Therefore, the arrangement of the mounting part 342 makes it convenient to mount and connect the plurality of conductive members 344.

Further, in some exemplary embodiments shown in the figures, the electric connection part 30 may include a plurality of conductive members 344, one or more of the plurality of conductive members 344 may be used for connection with the positive terminal of the battery, one or more of the plurality of conductive members 344 may be used for effecting a connection with the negative terminal of the battery, and one or more of the plurality of conductive members 344 may be used for a connection with a signal wire of the battery. One end of the plurality of conductive members 344 may be arranged in the mounting part 342, and the other part of the plurality of conductive members 344 may protrude from the mounting part 342, and then the mounting part 342 may be covered by these covering members 32. The mounting part 342 may be fixedly connected to the circuit board 20. The portion of the plurality of conductive members 344 protruding from the mounting part 342 may be connected to the battery connection terminal of the battery. In some exemplary embodiments, the mounting part 342 may be connected to the circuit board 20 through soldering/welding. Since the plurality of conductive members 344 are arranged in the mounting part 342 and the mounting part 342 may be fixedly connected to the circuit board 20, in the process of connecting the plurality of conductive members 344 and the circuit board 20, this may avoid the displacement of the plurality of conductive members 344 and an undesirable connection of the plurality of conductive members 344 with the circuit board 20.

Referring to FIG. 3, and FIG. 5 to FIG. 8, the sealing ring 40 may be arranged in the first recess 322 on the outer peripheral surface of the covering member 32, that is, the sealing ring 40 may be arranged in the outer peripheral surface of the electric connection part 30 that extends outside the housing 10. The sealing ring 40 may be used to seal, when the electric connector 100 is mounted on the movable platform 1000, the gap between the electric connection part 30 and the casing 200 of the movable platform 1000, so as to isolate the circuit board 20 in the housing 10.

The sealing ring may be in the shape of a runway, which matches the shape of the first recess 322. In some exemplary embodiments, the sealing ring 40 may be made of silica gel. It should be understood that, in some exemplary embodiments, the sealing ring 40 may be made of other materials and not limited to silica gel.

Specifically, when the electric connector 100 is mounted to the movable platform 1000, the housing 10 may be located inside the casing 200 of the movable platform 1000, and the sealing ring 40 may seal the gap between the electric connection part 30 and the housing opening 220 of the movable platform 1000 to isolate the circuit board 20 in the housing 10, so that water vapor outside the movable platform 1000 may not easily enter the casing 200, thereby avoiding water vapor to short circuit the circuit board 20. Taking agricultural unmanned aerial vehicles as an example, the agricultural unmanned aerial vehicles are mainly used for spraying irrigation. During operation, the sprayed liquid in the air lead to water vapor. A significant amount of water vapor entering the housing 10 may short the circuit board 20. In some exemplary embodiments, because of the sealing ring 40, the gap between the electric connection part 30 and the housing opening 220 is sealed by the sealing ring 40, which may isolate the circuit board 20 so that water vapor does not easily enter the housing 10.

Referring to FIG. 5 to FIG. 8, in some exemplary embodiments, the elastic body 50 may be in the shape of a substantially cylindrical ring. The elastic body 50 may be arranged at the location where the fourth recess 146 is located, that is, the elastic body 50 may be arranged between the mounting post 14 and the hole wall of the mounting hole 22. The elastic body 50 may be used to make the circuit board 20 and the electric connection part 30 displaceable with respect to the housing 10. In this way, the setting position of the elastic body 50 may be limited by the fourth recess 146. Thus, on the one hand, this may facilitate the arrangement of the elastic body 50 and; on the other hand, the fourth recess 146 may also limit the position of the elastic body 50, to avoid the failure of the displaceable connection caused by the elastic body 50 being detached from the mounting post 14, thereby ensuring the reliability of the displaceable connection. The elastic body 50 may be used to make the circuit board 20 and the electric connection part 30 displaceable with respect to the housing 10. Therefore, the displaceable connection between the circuit board 20 and the housing 10 may be achieved.

Specifically, the elastic body 50 may be connected to the mounting post 14 through an interference fit, which prevents the displacement of the elastic body 50. The elastic body 50 may be elastically deformable, and in the event of relative movement between the circuit board 20 and the housing 10, the elastic body 50 may be elastically deformed to offset the transmission of vibration between the circuit board 20 and the housing 10.

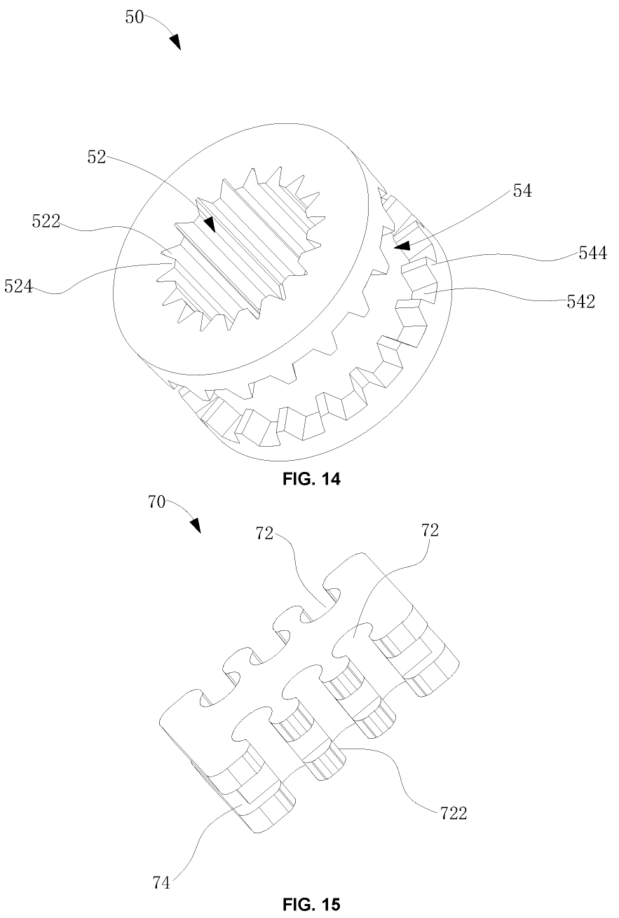

Referring to FIG. 14, in some exemplary embodiments, the elastic body 50 may be provided with a second through hole 52, and the mounting post 14 may penetrate the second through hole 52 which has a convex and concave hole wall (with protrusions and recesses). The convex and concave hole wall of the second through hole 52 may provide additional space for the deformed elastic body 50, allowing the elastic body 50 to have greater and easier elastic deformation and respond in a timely manner to the vibration of the housing 10 and the electric connection part 30. The structure forming the convex and concave shape may be a regular structure or an irregular structure. The regular structure may include convex and concave structures arranged in a certain period. In this way, the elastic body 50 may be able to undergo a large elastic deformation, allowing a large relative displacement range between the electric connection part 30 and the housing 10.

Specifically, in the example shown in FIG. 14, the hole wall of the second through hole 52 may have a serrated cross-section along the radial direction of the second through hole 52. In this way, the structure of a convex and concave shape may be simpler and easier to achieve. Specifically, the structure of the serrated shape may include a plurality of elongated fifth recesses 522 and a plurality of elongated first projections 524 in alternating sequence and elongated along the periphery of the elastic body 50, and the plurality of first projections 524 and the plurality of fifth recesses 522 extend along the length of the elastic body 50. The plurality of first projections 524 may abut against the mounting post 14. In the case where the circuit board 20 or housing 10 has a vibration, the plurality of fifth recesses 522 may provide additional space to make it easier for two adjacent first projections 524 to move closer or farther apart so as to offset the vibration.

In addition, referring to FIG. 14, the outer peripheral surface of the elastic body 50 may be provided with a sixth recess 54, and the sixth recess 54 may be ring-shaped. The periphery of the mounting hole 22 on the circuit board 20 may be located in the sixth recess 54, thereby allowing 360-degree positioning and mounting for the mounting hole 22. In some exemplary embodiments, the sixth recess 322 may be formed through recessing the outer periphery of the elastic body 50 toward the interior of the elastic body 50. It should be understood that, in some exemplary embodiments, the sixth recess 54 may also be arranged on a baffle protrudingly provided on the outer periphery of the elastic body 50. Therefore, on the one hand, the sixth recess 54 may achieve positioning assembly of the periphery of the mounting holes 22; on the other hand, it may avoid the elastic body 50 from being detached from the circuit board 20.

Further, the sixth recess 54 may include two opposing sides, which clamp the periphery of the mounting hole 22, and the two sides are in the convex and concave shape. In this way, the elastic body 50 may have a large elastic deformation when compressed to allow for a large relative displacement range between the electric connection part 30 and the housing 10.

In some exemplary embodiments, the sides of the sixth recess 54 may provide additional space for the deformation of the elastic body 50 to allow the elastic body 50 to have greater and easier elastic deformation and respond to vibration of the housing 10 and the electric connection part 30 in a timely manner. The structure forming the convex and concave shape may be a regular structure or an irregular structure. The regular structure may include convex and concave structures arranged in a certain period. In some exemplary embodiments, the two sides may be in the convex and concave shape. It should be understood that, in some exemplary embodiments, one of the two sides may be in such a convex and concave shape.

Specifically, in some exemplary embodiments, the two sides of the sixth recess 54 may be serrated. The structure of the serrated shape may include a plurality of elongated seventh recesses 522 and a plurality of elongated second projections 524 in an alternating sequence along the periphery of the elastic body 50, and the plurality of second projections 524 and the plurality of seventh recesses 522 extend along the length of the elastic body 50. The periphery of the mounting hole 22 of the circuit board 20 is located in the sixth recess 54, and the plurality of second projections 544 may abut against the perimeter of the mounting hole 22. In the case where the circuit board 20 or housing 10 has a vibration, the plurality of seventh recesses 542 may provide additional space to make it easier for two adjacent second projections 544 to move closer or farther away so as to offset the vibration. It should be understood that, in some exemplary embodiments, it may be the case that one of the two sides of the sixth recess 54 is in a serrated shape, and the other side may be in a ring shape or other shape, which is not limited herein.

Further, in some exemplary embodiments, the mounting of the elastic body 50 may be achieved by sleeving the elastic body 50 into the fourth recess 146 of the mounting post 14, and then arranging the elastic body 50 in the mounting hole 22, so that the periphery of the mounting hole 22 may be clamped between two sides of the sixth recess 54. Certainly, it should be understood that, in some exemplary embodiments, the arrangement of the elastic body 50 may be achieved by arranging the elastic body 50 in the mounting hole 22 on the circuit board 20, so that the periphery of the mounting hole 22 may be clamped between two sides of the sixth recess 54, and then the mounting post 14 may penetrate the second through hole 52 on the elastic body 50, so as to mount the elastic body 50. The mounting method may not be specifically limited, as long as the elastic body can be securely mounted between the mounting hole 22 and the mounting post 14, so that the circuit board 20 and the electric connection part 30 may displace relative to the housing 10.

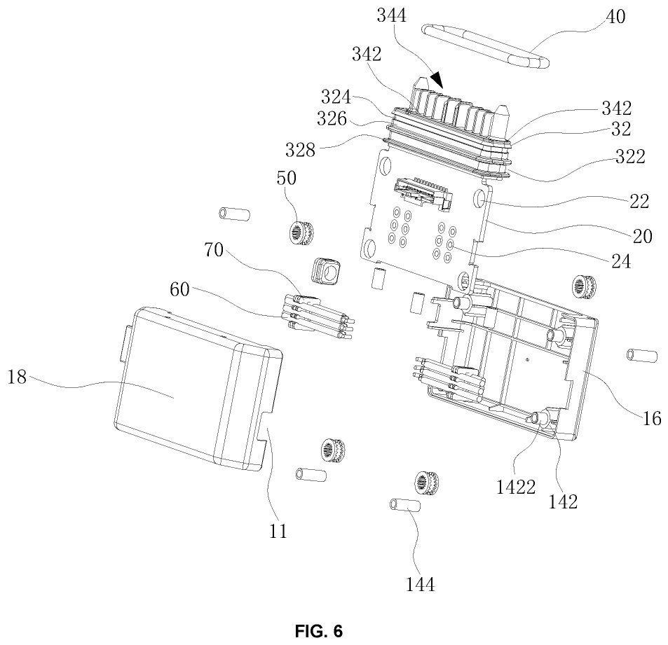

Referring to FIG. 6 to FIG. 8, in some exemplary embodiments, the power distribution wire 60 may be connected to the bounding pad 24 on the circuit board 20 for the electric connection between the power distribution wire 60 and the circuit board 20. The power distribution wire 60 can branch and output the current of the battery or the status signal of the battery transmitted through the electrical connector 100 to the load of the movable platform 1000. The movable platform 1000 may include a plurality of loads, each load is connected to the battery via the electric connector 100, the battery may transmit power and provide a status signal of the battery to the plurality of loads, and the plurality of loads may provide overload and/or temperature protection for the battery based on the status signal of the battery. In some exemplary embodiments, the power distribution wire 60 may be in two-way, one way of the power distribution wire 60 may include six positive wires and the other way of the power distribution wire 60 may include six negative wires. The plurality of loads may include six motors, with one motor connected to a positive line and a negative line, where the battery provides power to the motors. The plurality of loads may also include power-consuming components, such as central processors, graphics processors, sensors, etc.

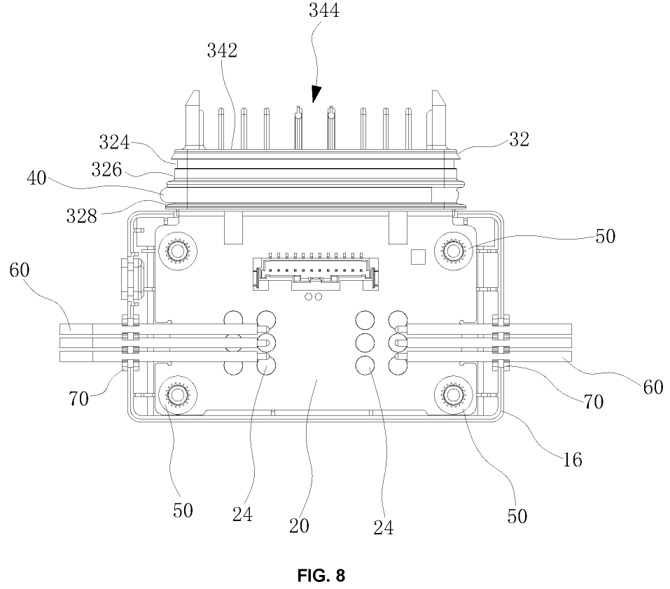

Referring to FIG. 7 and FIG. 8, in some exemplary embodiments, the quantity of the guide member may be two, and the two guide members 70 are mounted at the two third through holes 11 respectively. One way of the power distribution wire 60 may penetrate one of the guide members 70, the other way of the power distribution wire may penetrate the other guide member 70. In this way, the two ways of the power distribution wire 60 may penetrate from opposing sides of the plate of the housing 10, avoiding problems such as the power distribution wire 60 being too concentrated on one side of the housing 10, and causing the power distribution wire 60 to tangle.

Further, referring to FIG. 15, each of the two guide members 70 may be provided with a plurality of guide holes 72 and form a clamping part 74. Each of the two guide members 70 may be used to cover the power distribution wire 60, the clamping part 74 may be used to clamp the periphery of the third through hole 11 to mount the guide member 70 in the third through hole 11 and limit the position of the guide member 70.

In the orientation shown in the figure, the plurality of guide holes 72 may be provided along the thickness direction of the guide member 70 and arranged along the length direction thereof. The plurality of guide holes 72 may cover the power distribution wire 60, and the power distribution wire 60 may penetrate the plurality of guide holes 72. In this way, on the one hand, the two guide members 70 may organize the power distribution wire 60 to prevent the power distribution wire 60 from tangling during the relative movement of the circuit board 20 and the housing 10; on the other hand, in the case of relative movement between the circuit board 20 and the housing 10, the power distribution wire 60 may be protected by the two guide members 70 to avoid damage to the power distribution wire 60.

Specifically, the power distribution wire 60 may be led out from inside of the housing 10 through the two guide members 70. On the one hand, the two guide members 70 may organize the power distribution wire 60 through the guide hole 72 to avoid tangling of the power distribution wire 60; on the other hand, in some exemplary embodiments, since the circuit board 20 is displaceably connected to the housing 10, in the case of relative displacement between the circuit board 20 and the housing 10, the power distribution wire 60 may touch the hole wall of the third through hole 11 to cause wearing, the two guide members 70 may be used to protect the power distribution wire 60. Hence, the service life of the power distribution wire 60 may be extended, and the reliability of the electric connector 1000 may be improved.

Referring to FIG. 15, in some exemplary embodiments, each guide member 70 may be provided with six guide holes 72, and the six guide holes 72 are evenly divided into two rows. One way of the power distribution wire 60 may include six positive wires, the other way of the power distribution wire 60 may include six negative wires, the six positive wires may separately pass through one row of the plurality of guide holes 72, and the six negative wires may separately pass through the other row of the plurality of guide holes 72. In this way, each positive wire and each negative wire pass through one guide hole 72 correspondingly, thus avoiding problems such as tangling of the power distribution wire 60 caused by many the power distribution wires 60 coming out from one side of the housing 10. In some exemplary embodiments, three guide holes 72 may be provided at one of the two symmetrical ends of each guide member 70, and the power distribution wire 60 may penetrate the guide holes 72 along the thickness direction of the guide member 70.

Further, in some exemplary embodiments, the hole wall of each of the guide hole 72 may be formed with a second notch 722, and the second notch 722 may be used for the power distribution wire 60 to enter the guide hole 72 and then exit the guide hole 72. Specifically, when mounting the power distribution wire 60, it is only necessary to insert the power distribution wire 60 into the guide hole 72 through the second notch 722 in order to mount the power distribution wire 60 and isolate it from the housing 10, thus preventing wire tangling in the event of relative movement between the power distribution wire 60 and the housing 10. In addition, when mounting the power distribution wire 60, it is only necessary to place the power distribution wire 60 at the second notch 722, and then gently press the power distribution wire to fit it into the guide hole 72, and when removing the power distribution wire 60, the power distribution wire 60 may be pulled out from the second notch 722 by a small force to disengage the guide hole 72, thus making the assembly and disassembly of the power distribution wire 60 easier and more convenient.

Referring to FIG. 15, in some exemplary embodiments, the clamping part 74 may be located in a slot on two sides of the guide member 70, when mounting the guide member 70, only the periphery of the third through hole 11 needs to be mounted into the slot to mount the guide member 70. Specifically, in some exemplary embodiments, the two guide members 70 may be elastic members, such as made of silicone. In this way, the two guide members 70 may be deformed under an external force, and when mounting the two guide members 70, it is only necessary to press the two guide members 70 into the two third through holes 11, so that the periphery of the third through hole 11 may be clamped by the clamping part 74. Meanwhile, when replacing the guide member 70, the guide member 70 may be pulled out directly without the need to disassemble the housing 10 of the electric connector 100, making the operation convenient and simple. In addition, the two guide members 70 may be made of an elastic material, so that the elastic member may provide sufficient protection for the power distribution wire 60, thus avoiding damage to the power distribution wire 60 when the two guide members 70 are moved under an external force.

As seen from the above, in some exemplary embodiments, the sealing ring 40 may seal the gap between the electric connection part 30 and the casing 200 of the movable platform to achieve a waterproof effect. It should be understood that, in some exemplary embodiments, when the electric connector 100 is mounted on the movable platform 1000, the second recess 324 may be sleeved with a rubber ring (not shown in the figure). In this way, the waterproof performance and the appearance of the electric connector 100 may be further improved.

Specifically, referring to FIG. 3, when the electric connector 100 is mounted to the movable platform 1000, the electric connection part 30 may extend from the first through hole 12, the sealing ring 40 may be located inside the casing 200, the second recess 324 may be located outside the casing 200, and a rubber ring may be provided at the second recess 324. Thus, the rubber ring may cover the gap between the electric connection part 30 and the hole wall of the housing opening 220 to further enhance the waterproof performance of the electric connector 100. In addition, when mounting the rubber ring, the rubber ring may be mounted at the location of the second recess 324, thus the assemble position of the rubber ring may be limited by the second recess 324. On the one hand, this may facilitate mounting the rubber ring; on the other hand, the second recess 324 may limit the position of the rubber ring to avoid the failure of the seal cause by the detachment of the rubber ring from the electric connection part 30, thereby ensuring the reliability of the seal.

The following describes the work mechanisms in some exemplary embodiments of the present disclosure in details.

Referring to FIG. 3 and FIG. 5, in some exemplary embodiments, the elastic body 50 may be between the hole wall of the mounting hole 22 of the circuit board 20 and the mounting post 14 of the housing 10, so that the circuit board 20 and the electric connection part 30 that is fixedly connected to the circuit board 20 may be displaceable relative to the housing 10. Therefore, when the battery is mounted to the movable platform 1000, the electric connection part 30 of the battery and the electric connection part 30 of the electric connector 100 may be securely connected to each other for the transmission of the battery electrical signal. During the movement, the movable platform 1000 may have a vibration, and the movable platform 1000 may transfer the vibration to the housing 10 via the casing 200, thereby the housing 10 may vibrate therewith. Since the circuit board 20 is connected to the housing 10 in a displaceable connection, there is a certain relative movable distance between the circuit board 20 and the housing 10. Therefore, during the vibration of the housing 10, the electric connection part 30 of the electric connector 100 and the circuit board 20 do not vibrate or only have a small vibration due to such a distance, so as to ensure that there is no relative movement or small relative movement between the electric connector 100 and the battery, and avoid wearing of the two electric connection parts 30. Similarly, in the case where the battery has a vibration, the battery may drive the electric connection part 30 of the electric connector 100 to displace, thereby the circuit board 20 displacing relative to the housing 10, the housing 10 does not vibrate or has a small vibration, thereby avoiding the wearing between the two electric connection parts 30.

Meanwhile, due to the existence of the sealing ring 40, when the electric connector 100 is mounted to the movable platform 1000, the housing 10 may be located inside the casing 200 of the movable platform 1000, and the sealing ring 40 may seal the gap between the electric connection part 30 and the housing opening 220 of the movable platform 1000, to isolate the circuit board 20 inside the housing 10, so that water vapor outside the movable platform 1000 may not easily enter the gap on the casing 200, thereby avoiding water vapor from causing a short circuit of the circuit board 20.

Further, in some exemplary embodiments, the circuit board 20 may be fixedly connected to the electric connection part 30, the circuit board 20 may be displaceably connected to the housing 10, so that the circuit board 20 and the electric connection part 30 may be displaceable with respect to the housing 10. Therefore, during the vibration of the housing 10, there may be no relative movement or less relative movement between the electric connector 100 and the battery, so as to avoid the wearing of the two electric connection parts 30.

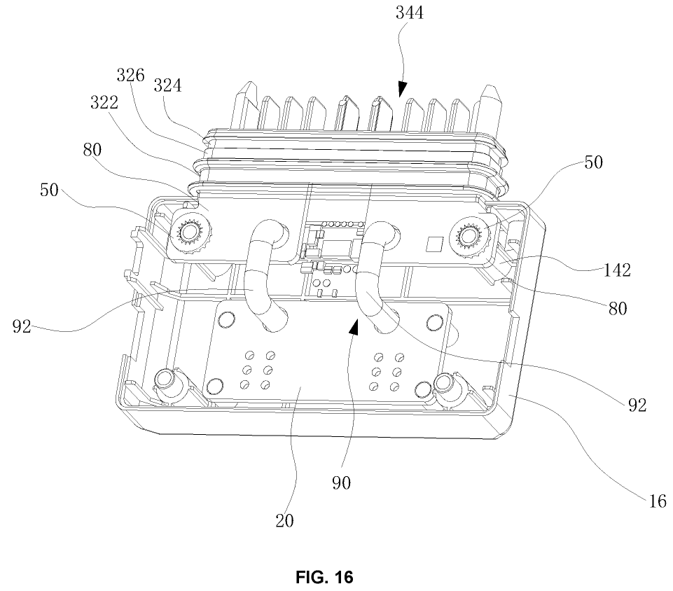

Referring to FIG. 16 to FIG. 18, in some exemplary embodiments of an electric connector 100a circuit board 20 may be fixedly connected to a housing 10, an electric connection part 30 may be displaceably connected to the housing 10, to ensure the electric connection part 30 to be displaceable relative to the housing 10 and the circuit board 20. That is, in some exemplary embodiments, the circuit board 20 and the housing 10 may be fixedly connected, and the electric connection part 30 and the housing 10 may be displaceably connected. In this way, during the vibration of the housing 10, it may ensure that there is no relative movement or less relative movement between the electric connector 100 and the battery, so as to avoid the wearing of the electric connection part 30 and the battery connection terminal.

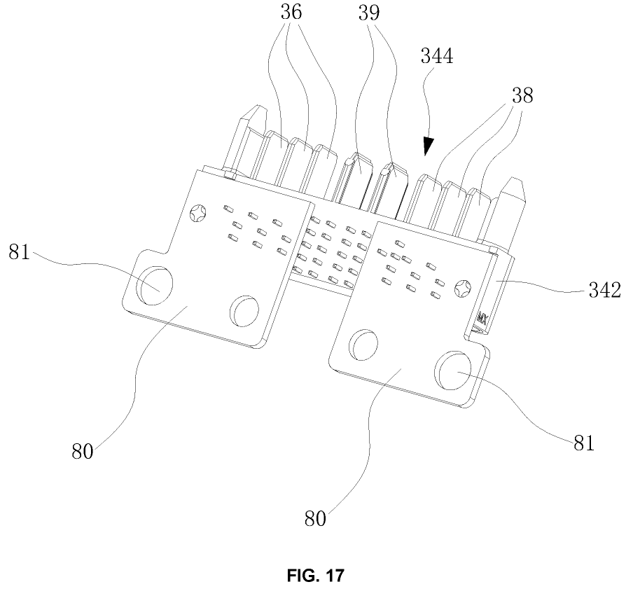

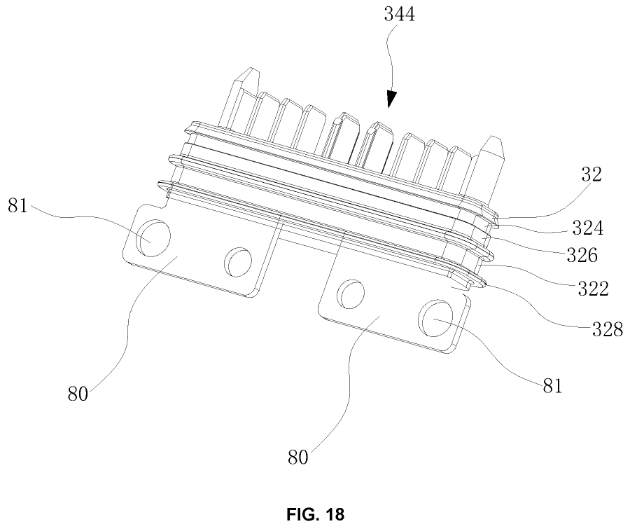

Referring to FIG. 17 and FIG. 18, in some exemplary embodiments, the electric connector 100 may further include at least one connecting plate 80. The housing 10 may be provided with at least one mounting post 14, the electric connection part 30 may be fixedly connected to the at least one connecting plate 80. A mounting hole 82 may be provided on the at least one connecting plate 80, the mounting post 14 may penetrate the mounting hole 22, an elastic body 50 may be provided between the mounting post 14 and the hole wall of the mounting hole 22, so that the electric connection part 30 becomes displaceable relative to the housing 10. That is, the mounting post 14 of the housing 10 may penetrate the mounting hole 82 of the at least one connecting plate 80 but not the circuit board 20, and the elastic body 50 may be arranged between the hole wall of the mounting hole 82 of the at least one connecting plate 80 and the mounting post 14 of the housing 10. Specifically, the specific structure of the mounting post 14 and the elastic body 50 may be the same as described previously.

In some exemplary embodiments, the at least one connecting plate 80 may be an insulating plate or a conductive plate.

Referring to FIG. 16, when the connecting plate 80 is a conductive plate, the conductive plate is electrically connected to an electric connection part 30 and a circuit board 20 respectively, so that the circuit board 20 may process electrical signal output from the battery. It should be understood that, the connecting plate 80 may conduct electricity. In this way, when connected, only wires are required to connect the circuit board 20 and the conductive plate to achieve the connection between the circuit board 20 and the electric connection part 30, thereby enabling the circuit board 20 to process the electrical signal output from the battery.

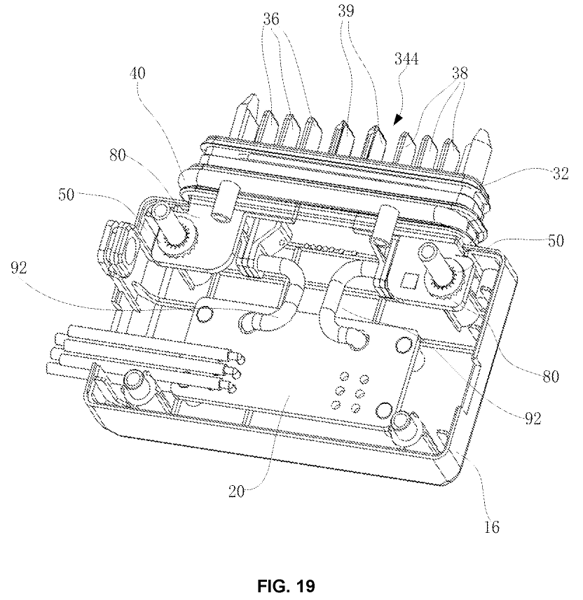

Referring to FIG. 19, when the connecting plate is an insulating plate, an electric connection part 30 may be electrically connected to a circuit board 20 via a flexible wire 90, to allow the circuit board 20 to process electrical signal output from the battery. In this way, the electric connection part 30 may be directly connected to the circuit board 20 through the flexible wire 90, the flexible wire 90 may have a certain degree of flexibility, so that the connection state between the electric connection part 30 and the circuit board 20 is not affected when the electric connection part 30 displaces with respect to the housing 10 and the circuit board 20. Specifically, the electric connection part 30 may include a covering member 32 and an electric connection member 34; the electric connection member 34 may protrude from the covering member 32. The electric connection member 34 may be electrically connected to the battery, and be electrically connected to the circuit board 20 through the flexible wire 90. Certainly, it should be understood that, in some exemplary embodiments, when the connecting plate 80 is a conductive plate, the circuit board 20 may also directly connected to an electric connection part 30 via a flexible wire 90 but not the conductive plate.

Further, referring to FIG. 16 and FIG. 17, in some exemplary embodiments, when the connecting plate 80 is a conductive plate, an electric connection part 30 may include a positive pin 36 and a negative pin 38, the quantity of the connecting plate 80 may be at least two, the two connecting plates 80 are respectively connected to the positive pin 36 and the negative pin 38 of the electric connection part 30, and each of the connecting plates 80 is connected to the circuit board 20 via a first flexible wire 92. In addition, in some exemplary embodiments, an electric connection part 30 may further include a signal pin 39; the signal pin 39 may connect to a circuit board 20 via a second flexible wire.

In this way, each of the positive pins 36, the negative pins 38 and the signal pins 39 of the electric connection part 30 may connect to the circuit board 20 via corresponding flexible wires 90, to allow the circuit board to process electrical signal output from the battery, to allow the circuit board 20 to distribute power supply from the battery and process electrical signal output from the battery. It should be noted that the second flexible wire and the connecting plate to connect the signal pin 39 are not shown in the figures.

In some exemplary embodiments, a positive pin 36, a negative pin 38, and a signal pin 39 of an electric connection part 30 may share two connecting plates 80. It should be understood that, in some exemplary embodiments, an electric connection part 30 may include a positive pin 36, a negative pin 38 and a signal pin 39. The quantity of a connecting plate 80 may be three, the three connecting plates 80 may be used to connect the positive pin 36, the negative pin 38 and the signal pin 39 of the electric connection part 30, and each of the connecting plates 80 may be connected to the circuit board 20 through the flexible wire 90. Certainly, the quantity of the connecting plate 80 may also be greater than three, as long as each pin may be electrically connected to the circuit board 20. This is not limited herein. It should be noted that the connecting plate that connects to the signal pin 39 is not shown in the figures.

It should be understood that, in some exemplary embodiments of the present disclosure, each of a plurality of conductive members 344 may include a positive pin 36, a negative pin 38 and a signal pin 39. That is, the electrical connection between the plurality of conductive members 344 and a plurality of battery connection terminals of a battery is actually the connection between the above pins and the battery connection terminals. Specifically, in some exemplary embodiments of the present disclosure, a battery connection terminal may also include a plurality of pins, the quantity of the pins may be equal to or greater than the quantity of pins of an electric connection part 30, and it is only necessary to ensure that each pin on the electric connection member 30 may be electrically connected to the corresponding pin on the battery connection terminal. In addition, as shown in the figure, the quantity of the positive pins 36 may be three, the quantity of the negative pins 38 may be three, and the quantity of the signal pins 39 may be two. It should be understood that, in some exemplary embodiments, the quantity of the plurality of positive pins 36 may also be greater than three, two, or one, the quantity of the plurality of negative pins 38 may also be greater than three, two, or one, and the quantity of the plurality of signal pins 39 may also be greater than two, or one.

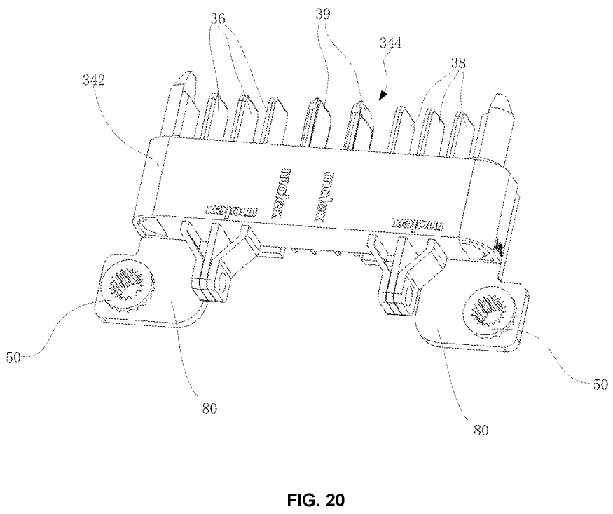

In addition, referring to FIG. 19 and FIG. 20, in some exemplary embodiments, a connecting plate 80 may also be an insulating plate. In such a case, a circuit board 20 may be directly connected to a positive pin 34 and a negative pin 38 via a first flexible wire 92 and a second flexible wire (not shown in the figures) respectively, and the connecting plate 80 may be fixedly connected to an electric connection part 30, and displaceably connected to a housing 10 without being electrically conductive. This also enables the electrical connection of each pin to the circuit board 20 without affecting the displacement of the electric connection part 30.

It should be understood that, in some exemplary embodiments of the present disclosure, a circuit board may be used to distribute power supply from the battery.

In addition, in some exemplary embodiments of the present disclosure, a circuit board 20 may be used to process the signal output from the battery. For example, the circuit board 20 may process the signal output from a battery to identify identification characteristics of the battery, which may include a signal, a brand name and a power supply capacity of the battery, etc. In this way, the circuit board 20 may identify whether the battery is a preset type of battery, which may ensure the uniqueness of the battery for a movable platform 1000 so as to prevent mismatch between the battery and the movable platform, which may damage or even burn the movable platform 1000. In addition, in some exemplary embodiments, a circuit board 20 may also be used to obtain a temperature signal of a battery, and send a signal to a power system of a movable platform when the temperature is too high. For example, a flight control system and a power system of an agricultural unmanned aerial vehicle may prohibit the movable platform 1000 to move or return, etc.

In addition, in the above embodiments, the circuit boards 20 are arranged in a housing 10. It should be understood that, in some exemplary embodiments, a circuit board 20 may be mounted outside a housing 10, that is, in some exemplary embodiments, an electric connection part 30 may be displaceably connected to the housing 10, so that the electric connection part 30 may be displaceable with respect to the housing 10. The electric connection part 30 may be connected to an external battery and an external circuit board 20 respectively, to enable the circuit board 20 to process electrical signals output from the battery.

It should be understood that, in some exemplary embodiments, the circuit board 20 may be mounted outside the housing 10, the electric connection part 30 may be mounted in the housing 10 and at least one portion thereof may extend out of the housing 10, the electric connection part 30 may be electrically connected to the circuit board 20 via the flexible wire 90. It should be noted that, in some exemplary embodiments, the structure and connection may be the same as those described above, except that the circuit board 20 may be mounted outside the housing 10. For example, the structure of the electric connection part 30 may displace relative to the housing 10, and the specific structure of the electric connection part 30 may be the same as described above, and will not be repeated herein.

Further, in some exemplary embodiments, a flexible wire 90 may connect to the electric connection part 30 and pass through the housing 10 to connect to the circuit board 20 located outside of the housing 10. In addition, in this case, the housing 10 of the electric connector 100 may also be provided with a guide element similar to the guide member 70 described above, and the flexible wire 90 may penetrate through the guide element to lead the flexible wire 90 out of the housing 10 to connect the circuit board 20.

In summary, in some exemplary embodiments of the present disclosure, the electric connector 100 may include a housing 10, a circuit board 20, and an electric connection part 30. The circuit board 20 may be mounted in the housing 10 and may be used to connect to a load of a movable platform 1000. At least one portion of the electric connection part 30 may extend out of the housing 10A sealing ring 40 may be mounted in the outer peripheral surface of the electric connection part 30 that extend outside the housing 10. When the electric connector 100 is mounted on the movable platform 1000, the sealing ring 40 may be used to seal the gap between the electric connection part 30 and the casing 200 of the movable platform 1000, so as to isolate the circuit board 20 of the housing 10. The electric connection part 30 may be electrically connected to the circuit board 20 and an external battery respectively, so as to enable the circuit board 20 to process electrical signals output from the battery.

In some exemplary embodiments, the electric connection part 30 may displace relative to the housing 10, so that when the movable platform 1000 vibrates, the movement of the electric connection part 30 may be reduced, which may avoid the wearing of the electric connection part 30 and the battery connection terminal of the battery, so as to ensure the reliability of the electric connector 100. In addition, the sealing ring 40 may be arranged on the outer peripheral surface of the electric connection part 30 that extend outside the housing 10. When the electric connector 100 is mounted on the movable platform 1000, the sealing ring 40 may be used to seal the gap between the electric connection part 30 and the casing 200 of the movable platform 1000 to isolate the circuit board 20 of the housing 10, thereby avoiding short circuit, etc. of the circuit board 20, and ensuring the reliability of the electric connector 100.

In addition, in some exemplary embodiments of an electric connector 100 of the present disclosure, the electric connector 100 may include a housing 10, a circuit board 20 and an electric connection part 30; the circuit board 20 may be mounted in the housing 10 to connect to a load of a movable platform 1000. At least one portion of the electric connection part 30 may extend out of the housing 10, and a first recess 322 may be provided on the outer peripheral surface of the electric connection part 30 that extends outside the housing 10, the first recess 322 may be used to mount a sealing ring 40, the sealing ring 40 may be used to seal, when the electric connector 100 is mounted on the movable platform 1000, the gap between the electric connection part 30 and the casing 200 of the movable platform 1000 to prevent a circuit board 20 inside the housing 10 from being affected by the outside circumstance. The electric connection part 30 may be electrically connected to the circuit board 20 and an external battery respectively, to enable the circuit board 20 to process electrical signals output from the battery.

In some exemplary embodiments, the first recess 322 may be provided on the outer peripheral surface of the electric connection part 30 that extends outside the housing 10, the first recess 322 may be used to mount a sealing ring 40. In this way, the sealing ring 40 may be used to seal, when the electric connector 100 is mounted on the movable platform 1000, the gap between the electric connection part 30 and the casing 200 of the movable platform 1000 to prevent the circuit board 20 inside the housing 10 from being affected by the outside circumstance, thereby avoiding short circuit, etc. of the circuit board 20, and ensuring the reliability of the electric connector 100.

Moreover, in some exemplary embodiments of an electric connector 100 and a movable platform 1000 of the present disclosure, the electric connector 100 may include a housing 10, a circuit board 20 and an electric connection part 30, the circuit board 20 may be fixedly mounted in the housing 10. At least one portion of the electric connection part 30 may extend out of the housing 10, the electric connection part 30 may be displaceably connected to the housing 10, so that the electric connection part 30 may be displaceable with respect to the housing 10 and the circuit board 20. The electronic connection unit 30 may be used to connect to an external battery and the circuit board 20 respectively, so as to enable the circuit board 20 to process electrical signals output from the battery.

In some exemplary embodiments, the circuit board 20 may be fixedly mounted in the housing 10, the electric connection part 30 may be displaceably connected to the housing 10, so as to allow the electric connection part 30 to displace relative to the housing 10 and the circuit board 20. In this way, due to the electric connection part 30 may displace relative to the housing 10 and the circuit board 20. Therefore, when the movable platform 100 vibrates, the electric connection part 30 may displace to ensure that there is no relative movement or less relative movement between the electric connector 100 and the battery connection terminal of the battery, so as to avoid wearing of the electric connection part 30 and the battery connection terminal.

In addition, in some exemplary embodiments of an electric connector 100 of the present disclosure, the electric connector 100 may include a housing 10 and an electric connection part 30. At least one portion of the electric connection part 30 may extend out of the housing 10, the electric connection part 30 and the housing 10 are in a displaceable connection via an elastic body 50, so that the electric connection part 30 may be displaceable relative to the housing; in which the electric connection part 30 may be used to connect to an external battery and an external circuit board 20 respectively, to enable the circuit board to process electrical signals output from the battery.

In some exemplary embodiments, since the electric connection part 30 may displace relative to the housing 10, when a movable platform 100 vibrates, the electric connection part 30 may displace to ensure that there is no relative movement or less relative movement between the electric connector 100 and the battery connection terminal of the battery, so as to avoid the wearing of the electric connection part 30 and the battery connection terminal.

In summary, a movable platform 1000 in the present disclosure may include a casing 200 and the electric connector 100 as described above, the casing 200 is provided with a casing opening 220. The housing 10 may be located inside the casing 200, and the electric connection part 30 may protrude from the casing opening 220.

For the movable platform 1000, since the electric connection part 30 may displace relative to the housing 10 and the circuit board 20, when the movable platform 100 vibrates, the electric connection part 30 may displace to ensure that there is no relative movement or less relative movement between the electric connector 100 and the battery connection terminal of the battery, so as to avoid the wearing of the electric connection part 30 and the battery connection terminal. The sealing ring 40 may be used to seal, when the electric connector 100 is mounted on the movable platform 1000, the gap between the electric connection part 30 and the casing 200 of the movable platform 1000, to isolate the circuit board 20 of the housing 10, thereby avoiding short circuit, etc. of the circuit board 20, and ensuring the reliability of the electric connector 100.

In the description of the present disclosure, the terms “an embodiment”, “some embodiments”, “schematic embodiment”, “example”, “specific examples”, and “some examples” are used to describe specific features, structures, materials, or characteristics described in conjunction with an embodiment or example included in at least one embodiment or example of the present disclosure. In the present disclosure, schematic representations of the above terms do not necessarily refer to the same embodiment or example. Moreover, the specific features, structures, materials, or characteristics described may be combined in any one or more embodiments or examples in a suitable manner.

Even though the exemplary embodiments according to the present disclosure have been shown and described, a person of ordinary skill in the art may understand that some variations, modifications, replacements, and variants of these embodiments may be made without departing from the principles and purposes of the present disclosure. The scope of the present disclosure is limited by the claims and their equivalents.

What is claimed is:

1. An electric connector, comprising:
a housing;
a circuit board, fixedly mounted in the housing;
an electric connection part; and
a sealing ring on an outer peripheral surface of the at least one portion of the electric connection part that extends out of the housing, wherein
at least one portion of the electric connection part extends out of the housing,
the electric connection part and the housing are in a displaceable connection to allow the electric connection part to be displaceable relative to the housing and the circuit board,
the electric connection part is configured to electrically connect to an external battery and the circuit board respectively to enable the circuit board to process an electrical signal output from the battery,
the outer peripheral surface of the at least one portion of the electric connection part that extends out of the housing includes a first recess and a second recess spaced apart from the first recess,
the sealing ring is located in the first recess, and
upon mounting the electric connector on a movable platform, a rubber ring is sleeved over the second recess, and the sealing ring seals a gap between the electric connection part and a housing of a movable platform to isolate the circuit board in the housing.

2. The electric connector according to claim 1, wherein
the outer peripheral surface of the at least one portion of the electric connection part that extends out of the housing further includes a third recess that is in communication with the second recess; and
a depth of the second recess is different from the depth of the third recess.

3. The electric connector according to claim 1, wherein
the electric connection part includes a covering member and an electric connection member;
the covering member covers the electric connection member;
the electric connection member is electrically connected to the circuit board; and
the sealing ring is arranged on an outer peripheral surface of the covering member.

4. The electric connector according to claim 6, wherein
the electric connection member includes a mounting part and a plurality of conductive members;
a portion of the plurality of conductive members is arranged in the mounting part; and
the covering member covers the mounting part.

5. The electric connector according to claim 4, wherein the covering member has a friction with the housing of the movable platform when the electric connection part displaces relative to the housing.

6. The electric connector according to claim 4, wherein the covering member is made of a material with high wear resistance and high strength.

7. The electric connector according to claim 6, wherein the covering member is made of polyamide;
a flange is disposed on the outer peripheral surface of the at least one portion of the electric connection part that extends out of the housing;
the housing includes a first through hole;
the electric connection part extends from the first through hole; and
the flange covers a gap between the electric connection part and a hole wall of the first through hole.

8. The electric connector according to claim 1, further comprising:
at least one connecting plate including a mounting hole;
at least one mounting post disposed in the housing; and
an elastic body disposed between the at least one mounting post and a hole wall of the mounting hole, wherein
the electric connection part is fixedly connected to the at least one connecting plate,
the at least one mounting post passes through the mounting hole,
the elastic body enable the electric connection part to displace relative to the housing, and
the at least one connecting plate is an insulating plate or a conductive plate.

9. The electric connector according to claim 8, wherein
the at least one connecting plate is an insulating plate; and
the electric connection part is electrically connected to the circuit board via a flexible wire to enable the circuit board to process the electrical signal output from the battery.

10. The electric connector according to claim 8, wherein
the at least one connecting plate includes two conductive plates;
the electric connection part includes a positive pin and a negative pin;
the two connecting plates are respectively connected to the positive pin and the negative pin; and
each of the connecting plates is connected to the circuit board via a first flexible wire.

11. The electric connector according to claim 10, wherein the electric connection part further includes a signal pin connected to the circuit board via a second flexible wire.

12. The electric connector according to claim 8, wherein
the at least one connecting plate includes at least three conductive plates;
each conductive plate includes a positive pin, a negative pin and a signal pin;
the at least three connecting plates are respectively connected to the positive pin, the negative pin and the signal pin; and
each of the connecting plates is connected to the circuit board via a flexible wire.

13. The electric connector according to claim 1, wherein the circuit board is configured to distribute a power supply from the battery.

14. The electric connector according to claim 1, wherein the circuit board is configured to process the signal output from the battery.

15. The electric connector according to claim 8, wherein
the elastic body includes a second through hole;
the at least one mounting post passes through the second through hole; and
a hole wall of the second through hole is in a convex and concave shape.

16. The electric connector according to claim 1, wherein
the circuit board is connected with at least one power distribution wire,
the housing includes at least one third through hole,
the electric connector includes at least one guide member mounted in the at least one third through hole, and
the at least one guide member includes at least one guide hole to allow the at least one power distribution wire to pass through; or
the circuit board is connected with at least one power distribution wire,
the electric connector includes at least one guide member,
the housing includes two third through holes respectively arranged on opposite sides of the housing,
each of the two third through holes is mounted with a guide member,
the electric connector includes two ways of the power distribution wire,
one way of the at least one power distribution wire penetrates through one of the at least one guide member, and
the other way of the at least one power distribution wire penetrates through another one of the at least one guide member.

17. The electric connector according to claim 16, wherein at least one the power distribution wire is connected to the circuit board via a bonding pad.

18. The electric connector according to claim 16, wherein
the at least one guide member includes two opposing side surfaces; and
at least one of the two opposing side surfaces forms a clamping part to clamp a periphery of the at least one third through hole.

19. An electric connector, comprising:
a housing;
an electric connection part;
at least one connecting plate including at least one a mounting hole;
at least one mounting post; and
an elastic body disposed between the at least one mounting post and a hole wall of the at least one mounting hole, wherein
at least one portion of the electric connection part extends out of the housing,
the electric connection part and the housing are in a displaceable connection via the elastic body to allow the electric connection part to displace relative to the housing,
the electric connection part is configured to connect to an external battery and an external circuit board respectively to enable the circuit board to process an electrical signal output from the battery,
the electric connection part is fixedly connected to the at least one connecting plate,
the at least one mounting post passes through the at least one mounting hole, and
the elastic body allows the electric connection part to displace relative to the housing.

20. A movable platform, comprising:
a casing, including a casing opening; and
an electric connector in the casing and extending from the casing through the casing opening, including:
a housing,
a circuit board, fixedly mounted in the housing,
an electric connection part, and
a sealing ring on an outer peripheral surface of the at least one portion of the electric connection part that extends out of the housing, wherein
at least one portion of the electric connection part extends out of the housing,
the electric connection part and the housing are in a displaceable connection to allow the electric connection part to be displaceable relative to the housing and the circuit board,
the electric connection part is configured to electrically connect to an external battery and the circuit board respectively to enable the circuit board to process an electrical signal output from the battery,
the outer peripheral surface of the at least one portion of the electric connection part that extends out of the housing includes a first recess and a second recess spaced apart from the first recess,
the sealing ring is located in the first recess, and
upon mounting the electric connector on a movable platform, a rubber ring is sleeved over the second recess, and the sealing ring seals a gap between the electric connection part and a housing of a movable platform to isolate the circuit board in the housing.
